(19) United States
(12) Patent Application Publication
(10) Pub. No.: US 2007/0230261 A1
(43) Pub. Date: Oct. 4, 2007

(54) Nonvolatile semiconductor memory device and method for testing the same

(76) Inventors: Juerg Haufe, Dresden (DE); Konrad Seidel, Dresden (DE)

Correspondence Address: EDELL, SHAPIRO & FINNAN, LLC, 1901 RESEARCH BLVD., SUITE 400, ROCKVILLE, MD, 20850, US

(21) Appl. No.: 11/396,928

(22) Filed: Apr. 4, 2006

(51) Int. Cl. G11C 11/34; G11C 7/00; G11C 29/00; G11C 16/04

(52) U.S. Cl. 365/201; 365/185.18

(57) ABSTRACT

A nonvolatile semiconductor memory device includes transistor-based memory cells. Each memory cell has a first and a second source/drain region, a channel region separating the first and the second source/drain region, a storage layer and a control gate. The control gates of the memory cells are connected to word lines. The first and second source/drain regions are connected to bit lines respectively. Each memory cell may be programmed by injecting first charge carriers of a first polarity and may be erased by injecting second charge carriers having the opposite polarity into the storage layer respectively. By applying a high stress voltage between bit line and word line, weak insulator structures may break through such that they become detectable as short-circuits by a low voltage leakage test. By applying the stress voltage contemporaneously on both sides of the memory cells, an early overerase/overprogram, resulting from hot carrier injection, is avoided.

### TECHNICAL FIELD

The present invention relates to a nonvolatile electrically erasable programmable read only memory device, to a method of testing the nonvolatile electrically erasable programmable read only memory device and to a method of testing a memory cell of the nonvolatile electrically erasable programmable read only memory device.

### BACKGROUND OF INVENTION

Nonvolatile electrically erasable programmable read only memory devices (EEPROMs), also known as nonvolatile semiconductor memory devices (NVM) comprise arrays of identical memory cells. Each memory cell bases on a MOSFET transistor including a source, a drain, an access or control gate, and a storing layer.

The source and the drain are doped impurity diffusion regions being formed within a single crystalline semiconductor substrate and adjacent to a pattern surface of the semiconductor substrate. The doped impurity regions have a conductivity type that is opposite of that of the surrounding portion of the semiconductor substrate. A channel region having the conductivity type of the semiconductor substrate separates the source and the drain.

Above the channel region, an insulated storage layer is provided on the pattern surface. A bottom dielectric separates the insulated storage layer from the semiconductor substrate. A control gate is disposed on top of the insulated storage layer, wherein a top dielectric separates the control gate and the insulated storage layer. The control gate, the top dielectric, the storage layer and the bottom dielectric form a stack like gate structure.

The memory cell is programmed by injecting first charge carriers into the insulated storage layer. The memory cell is erased by either removing the first charge carriers from the storage layer or by compensating their charge by injecting second charge carriers having the opposite polarity of the first charge carriers.

Dependent on a resulting amount of charge being stored in the storage layer, a threshold voltage of the MOSFET is switched between a lower and a higher threshold value. The memory cell is read out by applying a read voltage between the control gate and the source, wherein the read voltage is higher than the lower threshold value and lower than the higher threshold value. The current that is induced by the read voltage between source and drain is measured. The measured current is high, if a low threshold voltage is programmed and the MOSFET is conductive. The measured current is low, if a high threshold value is programmed and the MOSFET remains nonconductive. Thus the charge stored in the storage layer represents the data stored in the memory cell.

In floating gate type memory cells, the storage layer is a conductive layer, typically a polycrystalline silicon (polysilicon) layer, which is embedded in a surrounding silicon oxide structure. In charge trapping type memory cells, the storage layer is a nonconductive layer, typically a silicon nitride layer that is sandwiched between two silicon oxide layers forming the top and the bottom dielectric layer respectively.

Different techniques are yet described for programming and erasing of nonvolatile memories. Typically, electrons are transferred to and from the storage layer by using Fowler-Nordheim tunneling or hot electron injection, wherein suitable voltages are applied between drain and control gate or source and control gate respectively to control the respective mechanism.

Further multi-bit memory cells are known to comprise more than one storage layer or being controlled such that more than two different threshold values are detectable.

A two bit nonvolatile electrically erasable and programmable semiconductor memory cell stores data in two physically separated and separately controllable sections of a charge trapping layer near the source and drain respectively. The two bits are programmed by channel hot electron injection, wherein the control gate is biased and a voltage difference is applied between source and drain to program the source-side bit and vice-versa to program the drain-side bit. Erasing involves a tunneling enhanced hot hole injection mechanism.

Within an array of memory cells, the control gates of a plurality of memory cells are typically arranged in a row and adjacent to one another such that the control gates form a contiguous word line. Alternatively, each control gate is connected to a word line via contact structures. Typically bit contact structures are provided above the pattern surface and adjoining the source and/or drain. Each bit contact structure connects the respective source or drain to a corresponding bit line that is disposed above the control gates. The sources and drains of adjacent memory cells of a row of memory cells may also form a contiguous buried bit line respectively. Then the bit contact structures are provided to connect the buried bit line to a high conductivity bit line, which is disposed above the stack-like gate structures. An insulator structure on the vertical sidewalls of the stack-like gate structure separates the control gate and the respectively adjacent bit contact structure.

Typically a test for defect detection (TfDD) is performed after fabrication of the memory device. During the test for defect detection a test voltage is applied between the word line and one of the bit lines, wherein the test voltage induces a test current. A comparatively high test current indicates an electrical short circuit between the bit line and the word line and suggests a defective insulator structure. The test voltage is low with respect to the erase voltage to avoid overerase issues.

### SUMMARY

In a first aspect the present invention provides a method for testing an electrically erasable programmable read only memory cell. An electrically erasable programmable read only memory cell is provided that comprises a first source/drain region, a second source/drain region, a channel region separating the first source/drain region and the second source/drain region, a storage element being insulated from the channel region, and a control gate being insulated from the storage element. A current between the first source/drain region and the second source/drain region is controlled by a gate potential being applied to the control gate and by a charge being stored in the storage element. The storage element is capable of being discharged/charged by applying an erase/program voltage between one of the source/drain regions and the control gate.

A stress voltage is substantially contemporaneously applied both between the first source/drain region and the control gate and between the second source/drain region and the control gate respectively. The stress voltage is substantially equal to the erase/program voltage or higher.

A leakage test voltage is applied between the control gate and the first source/drain region and a leakage current being induced by the leakage test voltage is measured.

Since a comparatively high stress voltage in the order of the erase voltage or higher is applied between the control gate and the respective source/drain region, an electrical field of comparatively high field strength results in insulator structures separating the control gate and its corresponding connection wiring on the one hand and the respective source/drain region and its connection wiring on the other hand. The increased field strength causes critically weak insulator structures (marginal shorts) to break through. Then a previously undetectable marginal short-circuit or near-short circuit is transformed into a permanent short circuit that can be reliably detected by applying a comparatively low test voltage between the control gate and the respective source/drain region and subsequently measuring a test current induced by the test voltage. The test voltage may be equivalent to that of a typical test for defect detection and may be low with respect to the stress voltage.

Due to overerase/overprogram mechanisms, the threshold voltage of a memory cell may be influenced by the number of erase cycles having been performed and the erase or program efficiency of each proceeding erase or program cycle. For example with increasing number of erase cycles with high erase efficiency the erase efficiency may deteriorate.

Since according to the invention the stress voltage is applied contemporaneously between both source/drain regions and the control gate, no channel hot carrier injection occurs that may result in a high efficiency erase cycle. The probability for charge carriers to be injected into the storage layer decreases. The erase efficiency during application of the stress voltage is low and erase efficiency remains unaffected.

Test coverage and device reliability are increased as not only permanent (hard) short circuits but also near-short circuits are detectable. The device performance remains unaffected.

In a second aspect, the present invention provides a method for testing an electrically erasable programmable read only memory device. A memory device is provided that includes a plurality of electrically erasable programmable read only memory cells, each memory cell comprising a first source/drain region, a second source/drain region, a channel region separating the first source/drain region and the second source/drain region, a storage element being insulated from the channel region, and a control gate being insulated from the storage element. A current between the first source/drain region and the second source/drain region is controlled by a gate potential being applied to the control gate and by a charge being stored in the storage element. The storage element is capable of being discharged/charged by an erase/program voltage that is applied between one of the source/drain regions and the control gate.

The memory device further comprises a first bit line connecting the first source/drain regions of the memory cells respectively, a second bit line connecting the second source/drain regions of the memory cells respectively, a word line connecting the control gates of the memory cells; and insulator structures separating respectively at least one section of the bit lines and one section of the word lines;

A stress voltage substantially equal to the erase/program voltage or higher is applied between the first bit line and the word line and contemporaneously between the second bit line and the word line, such that weak sections of the insulator structures may break through and become conductive.

A leakage test voltage is applied at least between the word line and the first bit line and a leakage current being induced by the leakage test voltage is measured.

Since a comparatively high stress voltage in the order of the erase/program voltage or higher is applied between the bit lines and the word line, an electrical field of comparatively high field strength is applied to the spacer insulator. The increased field strength between word line and bit line forces critically weak insulator structures, i.e., marginal shorts, between bit line and word line to break through. Then a previous marginal short-circuit or near-short circuit is transformed into a permanent short circuit that can be reliably detected by applying a test voltage between word line and bit line and measuring a test current induced by the test voltage. The test voltage may be equivalent to that of a typical test for defect detection and may be low compared to the stress voltage.

Since according to the invention the stress voltage is contemporaneously applied between both bit lines and the word line respectively, no channel hot carrier injection occurs that might result in a high efficiency erase or program. Test coverage is increased as not only permanent (hard) short circuits but also near-short circuits are detectable. Furthermore, device performance is not affected. The inventive method applies to a plurality of different types of electrically erasable programmable read only memory devices that include insulator structures separating word lines and bit lines and may apply advantageously to such types of nonvolatile memory devices having memory cells, the erase or program mechanism of which is closely connected to a channel hot carrier injection mechanism.

In a third aspect, the present invention provides an electrically erasable programmable read only memory device. The memory device includes a plurality of electrically erasable programmable read only memory cells, each memory cell comprising a first source/drain region, a second source/drain region, a channel region separating the first source/drain region and the second source/drain region, a storage element being insulated from the channel region, and a control gate being insulated from the storage element. A current between the first source/drain region and the second source/drain region is controlled by a gate potential being applied to the control gate and by a charge being stored in the storage element. The storage element is capable of being discharged/charged by an erase/program voltage being applied between one of the source/drain regions and the control gate.

The memory device further includes a first bit line connecting the first source/drain regions of the memory cells respectively, a second bit line connecting the second source/drain regions of the memory cells respectively, a word line connecting the control gates of the memory cells and insulator structures separating respectively at least in sections one of the bit lines and one of the word lines.

A voltage source of the memory device is capable of generating a stress voltage and a voltage routing unit is capable of switching the voltage source contemporaneously to the first bit line and the second bit line.

Since the stress voltage, which may be equal or higher than an erase/program voltage, can contemporaneously be applied to both bit lines, the memory device is capable of being tested by the method for testing an electrically erasable programmable read only memory device as described above.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

The disclosure will present in detail the following description of exemplary embodiments with reference to the following Figures.

FIG. 1 is a diagram illustrating the dependency of a required erase voltage on the number of preceding erase cycles.

FIG. 2 is a simplified cross-sectional view of an electrically erasable programmable read only memory cell having a weak shallow trench isolation structure between a control gate and a source region and being subjected to a test method according to exemplary embodiment of the invention.

FIG. 3 is a simplified cross-sectional view of an electrically erasable programmable read only memory cell having a defect-free spacer insulator and being subjected to a test method according to an exemplary embodiment of the invention.

FIGS. 4-5 are simplified cross-sectional views of another electrically erasable programmable read only memory cell having a weak spacer insulator and being subjected to a test method according to the exemplary embodiment of the invention.

FIG. 6 is a schematic illustration of a section of an electrically erasable programmable read only memory device according to a further exemplary embodiment of the invention.

Corresponding numerals in the different figures refer to corresponding parts and features unless otherwise indicated. The figures are drawn to clearly illustrate the relevant aspects of the preferred embodiments and are not necessarily in all respects drawn to scale.

### DETAILED DESCRIPTION

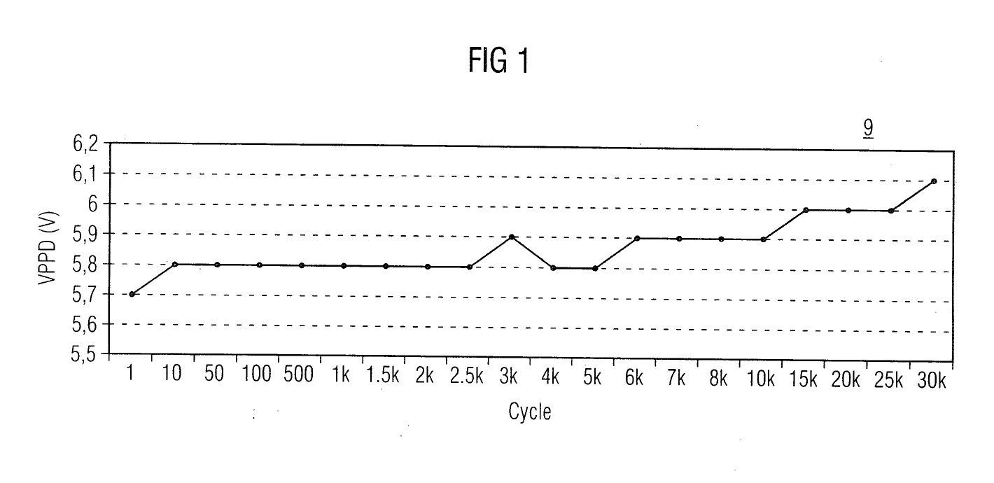

FIG. 1 illustrates a diagram 9 that plots the erase voltage, which is respectively required for reliably erasing an exemplary nonvolatile memory cell, against the number of erase cycles to which the exemplary nonvolatile memory cell has yet been subjected. The exemplary memory cell is a two-bit electrically erasable programmable read only memory device with a charge-trapping layer (NROM). Each of the NROM cell bits is programmed by channel hot electron injection and is erased by channel hot hole injection.

According to diagram 9, an erase voltage of 5.8 V is initially sufficient to reliably erase the exemplary memory cell during the first 1000 erase cycles. As the injection of the hot electrons in the charge trapping layer during programming and the injection of the hot holes being injected during erasing are not perfectly symmetrical, erase efficiency deteriorates significantly with increasing number of erase cycles. Therefore, with increasing number of erase cycles having been performed, the erase voltage is internally shifted to higher values. After the exemplary memory cell has experienced more than 20000 erase cycles, the erase voltage has to be shifted to at least 6.0 V to ensure reliable erasing.

An erase cycle with an erase voltage that is significantly higher than the minimum erase voltage being respectively required represents a high efficiency erase cycle. One single high efficiency erase cycle has the same effect as a plurality of erase cycles of minor efficiency and reduces life expectancy of the memory cell significantly. Therefore, high efficiency erase cycles are typically avoided during testing of the memory device.

On the other hand, diagram 9 shows that with ongoing time of operation the memory cell experiences increasing voltage stress and must withstand a voltage stress that was typically not applied during testing.

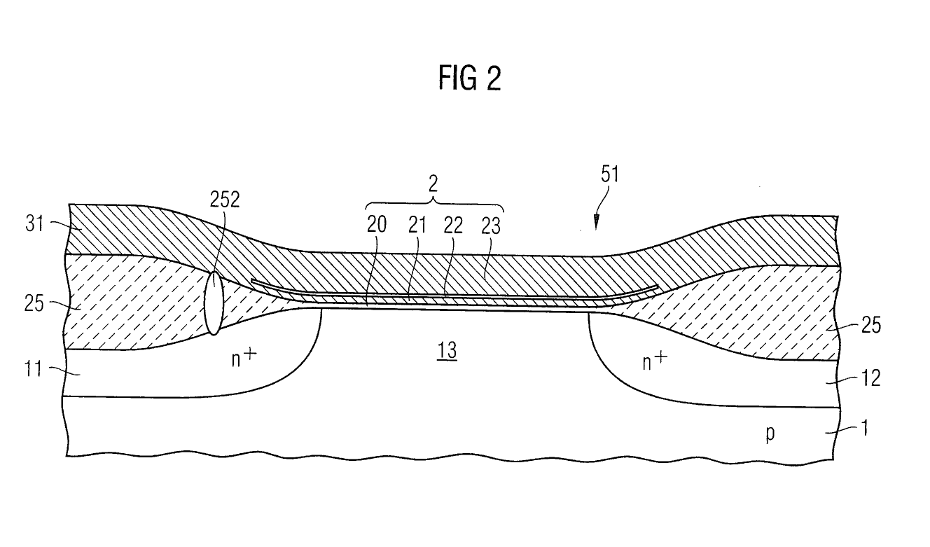

FIG. 2 illustrates a conventional electrically erasable programmable read only memory cell 51. Memory cell 51 includes a first source/drain region 11 and a second source/drain 12 being respectively provided as n-doped impurity regions within a p-doped semiconductor substrate 1. In the following, first source/drain region 11 is referred to as source 11 and second source/drain region 12 is referred to as drain 12. Semiconductor substrate 1 may be single crystalline silicon, such as a silicon wafer. A p-doped channel region 13 separates source 11 and drain 12. Channel region 13 adjoins a pattern surface 10 of semiconductor substrate 1. A bottom dielectric 20, which may be a thermally grown silicon oxide, adjoins channel region 13. Outside channel region 13, field dielectric structures 25 are formed along pattern surface 10. The field dielectric structures 25 may emerge from the same thermal growth process as bottom dielectric 20. Bottom dielectric 20 may have a thickness of about 5 to 15 nanometers. A charge-trapping layer 21 is disposed on the bottom dielectric 20 above channel region 13. Charge trapping layer 21 may have a thickness of about 3 to 8 nanometers. The material of charge trapping layer 21 may be silicon nitride. A top dielectric 22 is disposed on charge trapping layer 21. Top dielectric 22 may have a thickness of about 5 to 10 nanometers. The material of top dielectric 22 may be silicon oxide.

A word line 31 covers top dielectric 22 in sections and extends in a direction parallel to the section plane. Word line 31 forms in sections a control gate 23 of memory cell 51.

A defect 252 extending within field dielectric structure 25 between word line 31 and source 11 is shown. Defect 252 may be a weak section of field dielectric 25 being caused by a process abnormity. The insulating effect of the weak section may be sufficient to withstand a low test voltage, typically 2 Volts, as being applied during a conventional short-circuit test. During an erase cycle, a comparatively high erase voltage difference is applied between source 11 and word line 31, typically higher than 10 Volts. Additionally, for some types of memory cells, the erase voltage may be significantly increased during the lifetime of the memory cell. The erase voltage may then cause the weak section to break through such that defect 252 represents a short-circuit between source 11 and word line 31. As further the short-circuit occurs between world line 31 being connected to a plurality of memory cells 51 of a memory device and a bit line being connected to a further plurality of memory cells 51, a large block with a multitude of memory cells 51 fails. Redundant structures on the memory device may then not be sufficient to ensure further correct operation of the device.

A stress voltage that is higher than the test voltage may therefore be applied between source 11 and word line 31 during the test of memory cell 51 to burn up weak sections of field dielectric 25 already during the test of memory cell 51. Best test coverage may be achieved by applying a stress voltage that is higher than the erase voltage required towards the end of lifetime of the memory cell or the highest voltage difference being provided within the respective memory device.

Then in general a problem occurs due to the resulting voltage difference between source 11 and drain 12. Due to this voltage difference, charge carriers may be accelerated between source 11 and drain 12 or vice versa. Dependent on the polarity of the voltage at control gate 23, the accelerated hot electrons or holes may be injected into charge trapping layer 21. If exemplary memory cell 51 is programmed by channel hot electron injection and erased by channel hot hole injection, applying a stress voltage significantly higher than the currently required erase voltage would therefore result in injecting more holes into charge trapping layer 21 than may be compensated by electrons injected by a preceding or following program cycle. As a consequence, memory cell 51 may be overerased and defective.

By contemporaneously applying the stress voltage both between source 11 and word line 31 and between drain 12 and word line 31, no channel hot carrier injection occurs. The resulting erase efficiency is determined by other mechanisms of lower efficiency.

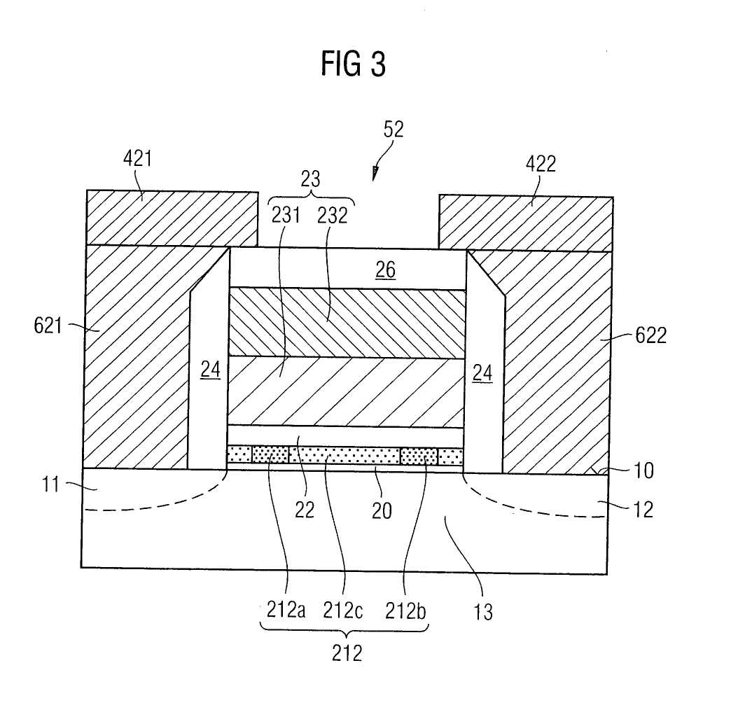

FIG. 3 refers to an electrically erasable programmable read only memory cell 52 capable of storing two bits of data in separated and separately controllable localized trapping regions 212a and 212b.

Memory cell 52 includes a first source/drain region 11 and a second source/drain 12 being respectively provided as n-doped impurity regions within a p-doped semiconductor substrate 1. Again, first source/drain region 11 is referred to as source and second source/drain region 12 is referred to as drain in the following. Semiconductor substrate 1 may be monocrystalline silicon, such as a silicon wafer. A p-doped channel region 13 separates source 11 and drain 12. Channel region 13 adjoins a pattern surface 10 of semiconductor substrate 1. A bottom dielectric 20, which may be a deposited or thermally grown silicon oxide, adjoins channel region 13. Bottom dielectric 20 may have a thickness of about 5 to 15 nanometers. A charge-trapping layer 212 is disposed on the bottom dielectric 20 above channel region 13. Charge trapping layer 212 may have a thickness of about 3 to 10 nanometers. The material of charge trapping layer 212 may be silicon nitride. Charge trapping layer 212 comprises a first and a second trapping region 212a, 212b near source 11 and drain 12 respectively. A top dielectric 22 is disposed on charge trapping layer 212. Top dielectric 22 may have a thickness of about 5 to 10 nanometers. The material of top dielectric 22 may be silicon oxide.

A control gate 23 including a polysilicon layer 231 covering the top dielectric 22 and a high conductivity layer 232 covering the polysilicon layer 231 is part of a word line (not shown). A cap layer 26 covers high conductivity layer 232. The word line extends orthogonally to the section plane of FIG. 3 and forms in sections control gate 23. Spacer insulators 24 extend along the verticals sidewalls of each memory cell 52.

Bit contact structures 621, 622 of polysilicon or a high conductive material connect source 11 and drain 12 to bit lines 421, 422 respectively. In one embodiment, the bit lines 421, 422 extend orthogonally to the section plane. Memory cell 52 is programmed using hot electron programming, wherein a programming voltage is applied to control gate 23 and to either source 11 or drain 12. Hot electrons are accelerated sufficiently to be injected into the respective trapping region 212a, 212b near where the programming voltage is applied. Reading is performed in the opposite direction. Both bits can be individually erased by applying a suitable erase voltage to control gate 23 and either source 11 or drain 12.

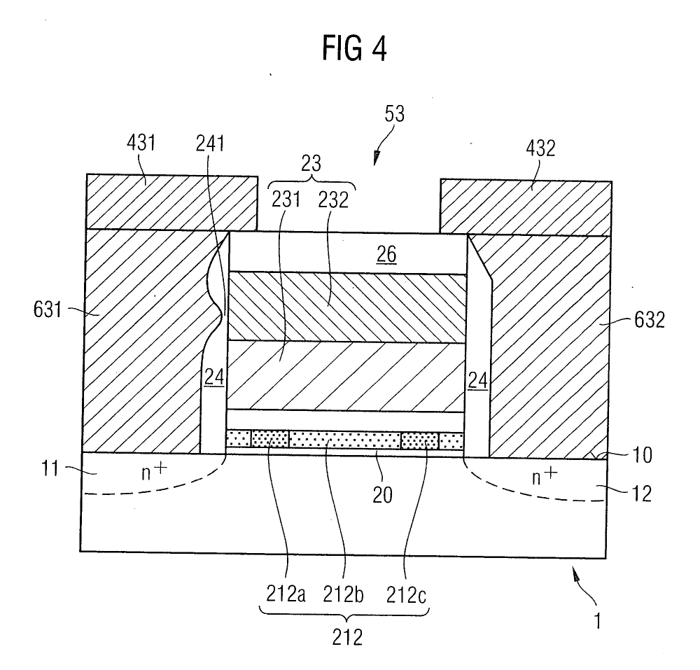

FIGS. 4 refers to an electrically erasable programmable read only memory cell 53 of the same type as that of FIG. 3 but having a weak spacer insulator 24. Due to deviations caused by production or by particle contamination, spacer insulator 24 is thinned between contact structure 631 and high conductivity layer 232 of control gate 23 in a weak section 241.

The remaining portion of insulator material between contact structure 631 and high conductivity 232 layer may be sufficient to suppress a leakage current between high conductivity layer 232 and contact structure 631 as long as the voltage applied between them does not exceed a critical threshold value. As long as the test voltage is comparable low, e.g., 2 Volts, a test for defect detection using the test voltage passes and does not indicate a failure. When after shipment and during the lifetime of the memory cell a higher erase voltage becomes necessary (see FIG. 1), the field strength in the thinned weak section 241 of spacer insulator 24 increases such that weak section 241 breaks through and memory cell 53 fails.

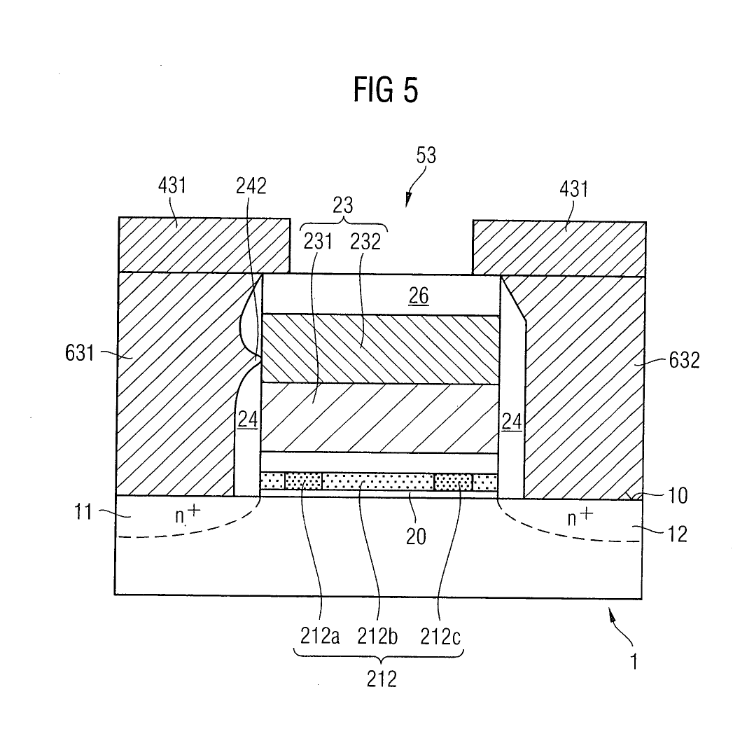

FIG. 5 illustrates the memory cell 53 of FIG. 4 with a short-circuit 242 resulting from weak section 241 (FIG. 4). Applying instead of the test voltage a stress voltage in the order of the erase voltage between source 11 and control gate 232 would, however, result in a high efficiency erase cycle due to channel hot hole injection. A high efficiency erase cycle results in an overerase of memory cell 53, and injects more holes in the charge trapping sections 212a, 212b than necessary for compensating the charge of previously injected electrons. Applying a stress voltage higher than the presently or initially required erase voltage, for example the erase voltage that is required towards the end of the lifetime of the memory cell, would result in a severe overerase that may damage the memory cell strongly.

If, however, the stress voltage is applied between source 11 and control gate 23 and contemporaneously between drain 11 and control gate 23, source 11 and drain 12 have the same potential and no channel hot hole injection occurs. As a consequence, the erase efficiency is poor and no overerase issue occurs. The properties of memory cell 53 remain unchanged. The stress voltage may be even in the order of the erase voltage or higher, especially in the order of the erase voltage required towards the end of the lifetime of memory cell 53 without pre-damaging memory cell 53.

Though explained in detail for two-bit NROM devices according to a hot electron injection program and hot hole injection erase scheme, the invention may also apply to other non-volatile memory cells as for example to memory cells following a band-to-band tunneling induced hot hole injection program and Fowler-Nordheim tunneling erase scheme.

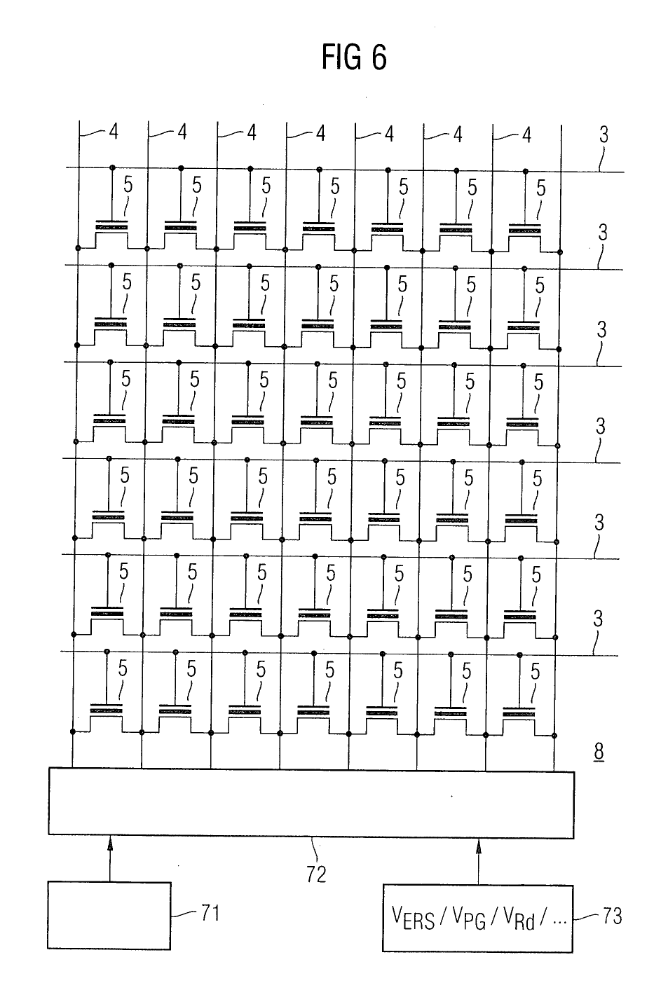

FIG. 6 illustrates schematically a section of a memory array of an exemplary memory device 8. A plurality of memory cells 5 is arranged in rows and lines. Word lines 3 connect control gates of a plurality of the memory cells 5 arranged in lines respectively. Bit lines 4 connect first and second source/drain regions of the memory cells 5 arranged in rows respectively.

A controllable voltage source 73 being capable of generating various voltages being applied to the bit lines 4 for proper operation of the memory cells 5 is connected to a voltage routing unit 72. Voltage routing unit 72 is capable of routing the voltages generated by voltage source 73 to selected bit lines 4 respectively. Though contemporaneous routing of an erase voltage generated by voltage source 73 to neighboring bit lines 4 is not required during normal operation of memory device 8, voltage routing unit 72 is capable of routing the erase voltage during a test mode to neighboring bit lines 4 that are connected to the same row of memory cells 5 respectively. Voltage routing unit 72 is connected to a test register 71. Test register 71 is controlled by an external or internal test controller and controls voltage routing unit 72.

While the invention has been described in detail and with reference to specific embodiments thereof, it will be apparent to one skilled in the art that various changes and modifications can be made therein without departing from the spirit a and scope thereof. Accordingly, it is intended that the present invention covers the modifications and variations of this invention provided they come within the scope of the appended claims and their equivalents.

### LIST OF REFERENCES

1 substrate
10 pattern surface
11 source
12 drain
13 channel region
2 gate stack
20 first dielectric layer
21 storage layer
212 charge trapping layer
212a first trapping region
212b second trapping region
212c non trapping region
22 second dielectric layer
23 control gate
231 polysilicon layer
232 high conductivity layer
24 sidewall spacer
241 weak section
242 short circuit
25 field dielectric
252 short circuit
26 cap layer
3 word line
4 bit line
421 bit line
422 bit line
431 bit line
432 bit line
5 memory cell
51 memory cell
52 memory cell
53 memory cell
621 bit contact
622 bit contact
631 bit contact
632 bit contact
71 test register
72 switching unit
73 voltage source
8 memory device
9 diagram

What is claimed is:

1. A method for testing an electrically erasable programmable read only memory cell, comprising:
providing an electrically erasable programmable read only memory cell comprising a first source/drain region, a second source/drain region, a channel region separating the first source/drain region and the second source/drain region, a storage element insulated from the channel region, and a control gate insulated from the storage element, wherein a current between the first source/drain region and the second source/drain region is controlled by a gate potential being applied to the control gate and by a charge being stored in the storage element, and wherein the storage element is capable of being discharged/charged by an erase/program voltage being applied between one of the source/drain regions and the control gate;
contemporaneously applying a stress voltage, substantially equal to the erase/program voltage or higher, between the first source/drain region and the control gate and between the second source/drain region and the control gate respectively;
applying a leakage test voltage between the control gate and the first source/drain region; and
measuring a leakage current induced by the leakage test voltage.

2. The method according to claim 1, wherein the storage element is capable of being charged by injection of first charge carriers with a first polarity and wherein the storage element is capable of being discharged through channel hot carrier injection of second charge carriers with a second polarity which is opposite to the first polarity, wherein the channel hot carrier injection of the second charge carriers is controlled by applying the erase/program voltage.

3. The method according to claim 2, wherein the storage element is a floating gate comprising a conductive material and is insulated from the control gate by a top dielectric, and wherein the erase/program voltage is at least 8 Volts.

4. The method according to claim 2, wherein the storage element is a charge trapping layer comprising a nonconductive material, and wherein the stress voltage corresponds to a final erase voltage of the memory cell.

5. The method according to claim 4, wherein the charge trapping layer comprises two separated and separately controllable charge-trapping areas.

6. The method according to claim 1, wherein the leakage test voltage is less than a fourth of the stress voltage.

7. A method for testing an electrically erasable programmable read only memory device, comprising:
(a) providing a memory device comprising:
a plurality of electrically erasable programmable read only memory cells, each memory cell comprising a first source/drain region, a second source/drain region, a channel region separating the first source/drain region and the second source/drain region, a storage element insulated from the channel region, and a control gate insulated from the storage element, wherein a current between the first source/drain region and the second source/drain region is controlled by a gate potential being applied to the control gate and by a charge being stored in the storage element, and wherein the storage element is capable of being discharged/charged by an erase/program voltage applied between one of the source/drain regions and the control gate;
a first bit line connecting the first source/drain regions of the memory cells respectively;
a second bit line connecting the second source/drain regions of the memory cells respectively;
a word line connecting the control gates of the memory cells; and
insulator structures respectively separating, at least in sections, one of the bit lines and one of the word lines;
(b) contemporaneously applying a stress voltage substantially equal to the erase/program voltage or higher between the first bit line and the word line and between the second bit line and the word line, such that weak sections of the insulator structures break through and become conductive;
(c) applying a leakage test voltage between the word line and the first bit line; and
(d) measuring a leakage current being induced by the leakage test voltage.

8. The method according to claim 7, further comprising: applying the leakage test voltage between the word line and the second bit line and measuring a further leakage current induced by the leakage test voltage.

9. The method according to claim 7, wherein the storage element is capable of being charged by injection of first charge carriers having a first polarity and wherein the storage element is capable of being discharged through channel hot carrier injection of second charge carriers having a second polarity which is opposite to the first polarity, wherein the channel hot carrier injection of the second charge carriers is controlled by applying the erase/program voltage.

10. The method according to claim 9, wherein the storage element is a nonconductive charge trapping layer, and wherein the stress voltage corresponds to a final erase voltage of the memory cell, wherein, at the end of the lifetime of the memory cell, the final erase voltage is applied as the stress voltage.

11. The method according to claim 10, wherein the charge trapping layer comprises two, separated and separately controllable, charge-trapping areas.

12. The method according to claim 7, wherein the stress voltage is at least 13 Volts.

13. The method according to claim 8, wherein the leakage test voltage is less than a fourth of the stress voltage.

14. An electrically erasable programmable read only memory device, comprising:
a plurality of electrically erasable programmable read only memory cells, each memory cell comprising: a first source/drain region, a second source/drain region, a channel region separating the first source/drain region and the second source/drain region, a storage element insulated from the channel region, and a control gate insulated from the storage element, wherein a current between the first source/drain region and the second source/drain region is controlled by a gate potential being applied to the control gate and by a charge being stored in the storage element, and wherein the storage element is capable of being discharged/charged by an erase/program voltage being applied between one of the source/drain regions and the control gate;
a first bit line connecting the first source/drain regions of the memory cells respectively;
a second bit line connecting the second source/drain regions of the memory cells respectively;
a word line connecting the control gates of the memory cells;
insulator structures separating respectively, at least in sections, one of the bit lines and one of the word lines;
a voltage source being capable of generating a stress voltage; and
a voltage routing unit capable of switching the voltage source contemporaneously to the first bit line and the second bit line.

15. The memory device according to claim 14, wherein the storage element is capable of being charged by injection of first charge carriers having a first polarity and wherein the storage element is capable of being discharged through channel hot carrier injection of second charge carriers having a second polarity, which is opposite to that of the first polarity, wherein the channel hot carrier injection of the second charge carriers is controlled by applying the erase/program voltage.

16. The memory device according to claim 14, wherein the storage element is a floating gate being conductive and being insulated from the control gate by a top dielectric.

17. The memory device according to claim 15, wherein the storage element is a nonconductive charge trapping layer.

18. The memory device according to claim 17, wherein the first charge carriers are electrons.

19. The memory device according to claim 18, wherein the charge trapping layer comprises two, separated and separately controllable, charge-trapping areas.

20. The memory device according to claim 14, wherein the voltage routing unit is capable of being controlled by a test register.

21. The memory device according to claim 20, wherein the test register is accessible via an internal or external test control unit.

22. The memory device according to claim 14, wherein the memory device is operable to control the charging and discharging of the individual storage elements with different and separately detectable amounts of charge, such that the memory cells operate in a multi-level operation mode.
